(19) United States
(12) Patent Application Publication
(10) Pub. No.: US 2026/0324367 A1
(43) Pub. Date: Oct. 15, 2026

(54) SEMICONDUCTOR TEST STRUCTURE AND TEST METHOD FOR INTERLAYER OVERLAY SHIFT OF METAL LAYERS

(71) Applicant: SwaySure Technology Co., Ltd., Shenzhen (CN)

(72) Inventor: Yuqian Chen, Shenzhen (CN)

(21) Appl. No.: 19/631,174

(22) Filed: Mar. 27, 2026

(30) Foreign Application Priority Data
Apr. 10, 2025 (CN) 202510446110.9

(51) Int. Cl. H10P 74/00; G01R 31/26; H10P 74/20

(52) U.S. Cl. CPC H10P 74/273; G01R 31/2601; H10P 74/203; H10P 74/207

(57) ABSTRACT

A semiconductor test structure includes a first metal line to be tested and a second metal line to be tested; the first conductive test portion of a conductive test structure and a first metal layer to be tested are distributed on the same layer, and the second conductive test portion of a conductive test structure and a second metal layer to be tested are distributed on the same layer; the first metal line to be tested and the second metal line to be tested are connected through via holes; a first test pad is connected to the first conductive test portion or the second conductive test portion; and a second test pad is connected to the first metal line to be tested or the second metal line to be tested.

### CROSS-REFERENCE TO RELATED APPLICATIONS

The present application claims priority to Chinese Patent Application No. 202510446110.9, filed on Apr. 10, 2025, the entire disclosure of which is hereby incorporated herein by reference.

### TECHNICAL FIELD

The present disclosure relates to the technical field of semiconductors, and in particular to a semiconductor test structure and a test method for interlayer overlay shift of metal layers.

### BACKGROUND

A memory is widely applied to mobile devices such as a mobile phone and a tablet computer due to the advantages of small volume, high integration level and high transmission speed. In the manufacturing process for a semiconductor structure, due to the influence of the manufacturing process and other factors, a shift phenomenon may occasionally occur between upper and lower conductive layers of a conductive column, thereby affecting the electric performance of devices. Therefore, it is necessary to detect the shift of the upper and lower conductive layers in the manufacturing process to evaluate the reliability of the manufacturing process.

However, when an existing test structure performs a breakdown voltage test and detects the presence of metal layer shift (overlay shift), it is necessary to achieve the shift in different directions through different test structures, resulting in more test structures and large area occupied by the test structures in a scribe line.

It should be noted that information disclosed in the background is only used to enhance the understanding of the background of the present disclosure, and thus, may include information that does not form the prior art known to those skilled in the art.

### SUMMARY

The present disclosure provides a semiconductor test structure and a test method for interlayer overlay shift of metal layers.

According to one aspect of the present disclosure, a semiconductor test structure is provided and includes:
a first metal layer to be tested and a second metal layer to be tested that are distributed in a stacked manner, wherein an interlayer dielectric layer is filled between the first metal layer to be tested and the second metal layer to be tested, the first metal layer to be tested comprises a metal line to be tested with an equal line width, and the second metal line to be tested comprises a second metal line to be tested with an equal line width;
a conductive test structure, including a first conductive test portion and/or a second conductive test portion, where the first conductive test portion and the first metal layer to be tested are distributed on a same layer, the second conductive test portion and the second metal layer to be tested are distributed on a same layer, the first conductive test portion has an equal line width everywhere, the second conductive test portion also has an equal line width everywhere, a distance between the first conductive test portion and the first metal line to be tested is equal everywhere, a distance between the second conductive test portion and the second metal line to be tested is equal everywhere,
the first metal line to be tested and the second metal line to be tested are connected through a plurality of via holes, and each of the plurality of via holes penetrates through the interlayer dielectric layer;
a first test pad, connected to the first conductive test portion or the second conductive test portion; and
a second test pad, connected to the first metal line to be tested or the second metal line to be tested.

According to one aspect of the present disclosure, a test method for interlayer overlay shift of metal layers is provided. The test method uses the semiconductor test structure according to the above. The test method includes:
detecting a breakdown voltage between the first metal line to be tested and the first conductive test portion; or detecting a breakdown voltage between the second metal line to be tested and the second conductive test portion;
comparing the breakdown voltage with a preset voltage value, and inferring that a shift phenomenon exists between the first metal line to be tested and the second metal line to be tested when the breakdown voltage exceeds a preset deviation range of the preset voltage value;
sectioning the semiconductor test structure in different directions to obtain microscopic morphology images of sections of the semiconductor test structure in different directions; and
according to the microscopic morphology images, determining existence of the shift phenomenon, and determining a shift direction.

According to one aspect of the present disclosure, a test method for overlay shift between metal layers is provided. The test method uses the semiconductor test structure according to the above. The test method includes:
measuring a resistance between the first metal line to be tested and the first conductive test portion; or measuring a resistance between the second metal line to be tested and the second conductive test portion;
comparing the resistance with a preset resistance value, and inferring that a shift phenomenon exists between the first metal line to be tested and the second metal line to be tested when the resistance exceeds a preset deviation range of the preset resistance value;
sectioning the semiconductor test structure in different directions to obtain microscopic morphology images of sections of the semiconductor test structure in different directions; and
according to the microscopic morphology images, determining existence of the shift phenomenon, and determining a shift direction.

It should be understood that the above general description and the following detailed description are exemplary and explanatory only and are not intended to limit the present disclosure.

### BRIEF DESCRIPTION OF THE DRAWINGS

The accompanying drawings herein, which are incorporated into and form a part of the description, illustrate the embodiments in line with the present disclosure and are used in conjunction with the description to explain the principles of the present disclosure. Apparently, the accompanying drawings in the following description show merely some embodiments of the present disclosure, and those of ordinary skill in the art may still derive other drawings from these accompanying drawings without creative efforts.

FIG. 1 is a schematic diagram of a semiconductor test structure according to an embodiment of the present disclosure.

FIG. 2 is a schematic diagram of a first metal line to be tested and a first conductive test portion according to an embodiment of the present disclosure.

FIG. 3 is a schematic structural diagram of a semiconductor structure when a conductive test structure only includes a first conductive test portion according to an embodiment of the present disclosure.

FIG. 4 is a schematic structural diagram of a semiconductor structure when a conductive test structure only includes a second conductive test portion according to an embodiment of the present disclosure.

FIG. 5 is a schematic diagram of a semiconductor test structure when a conductive test structure only includes a first conductive test portion and a line width of a first metal line to be tested is greater than that of a second metal line to be tested according to an embodiment of the present disclosure.

FIG. 6 is a schematic diagram of a semiconductor test structure when a conductive test structure only includes a first conductive test portion and a line width of a first metal line to be tested is less than that of a second metal line to be tested according to an embodiment of the present disclosure.

FIG. 7 is a schematic diagram of a semiconductor test structure when a conductive test structure only includes a second conductive test portion and a line width of a first metal line to be tested is greater than that of a second metal line to be tested according to an embodiment of the present disclosure.

FIG. 8 is a schematic diagram of a semiconductor test structure when a conductive test structure only includes a second conductive test portion and a line width of a first metal line to be tested is less than that of a second metal line to be tested according to an embodiment of the present disclosure.

FIG. 9 is a schematic diagram of a semiconductor test structure according to an embodiment of the present disclosure.

FIG. 10 is a schematic diagram of a semiconductor test structure according to an embodiment of the present disclosure.

FIG. 11 is a top view of a first metal line to be tested, a second metal line to be tested, a first conductive test portion and a second conductive test portion.

FIG. 12 is a schematic diagram of a semiconductor test structure according to an embodiment of the present disclosure.

FIG. 13 is a schematic diagram of a test method for interlayer overlay shift of metal layers according to an embodiment of the present disclosure.

FIG. 14 is a schematic diagram of a test method for interlayer overlay shift of metal layers according to another embodiment of the present disclosure.

FIG. 15 is a schematic structural diagram of a first metal layer to be tested, a second metal layer to be tested, and an interlayer dielectric layer according to an embodiment of the present disclosure.

FIG. 16 is a schematic diagram of a semiconductor test structure according to an embodiment of the present disclosure.

### DETAILED DESCRIPTION OF THE EMBODIMENTS

Exemplary embodiments are described more comprehensively hereinafter with reference to the accompanying drawings. However, the exemplary embodiments can be implemented in various forms and should not be construed as being limited to the embodiments described herein; on the contrary, these embodiments are provided, so that the present disclosure will be comprehensive and complete, and the concept of the exemplary embodiments will be completely conveyed to those skilled in the art. In the drawings, the same reference numeral denotes the same or similar structure, and thus their detailed description will be omitted. In addition, the drawings are only schematic illustrations of the present disclosure and are not necessarily drawn to scale.

Although relative terms such as “up” and “down” are used in this specification to describe the relative relationship of one component of an icon to another, these terms are used in this specification only for convenience, for example, according to the directions of the examples described in the drawings. It can be understood that if the device of the icon is turned upside down, the component described “above” will become the component described “below”. When a structure is “on” other structures, it may mean that a structure is integrally formed on other structures, or that a structure is “directly” arranged on other structures, or that a structure is “indirectly” arranged on other structures through another structure.

The terms “one”, “a/an”, “the” and “at least one” are used to indicate the existence of one or more elements/components/etc. The terms “including” and “having” are used to indicate an open-ended inclusion and mean that there may be other elements/components/etc. besides the listed elements/components/etc.; and the terms “first”, “second”, . . . and “eighth” are only used as marks, not to limit the number of their objects.

In the manufacturing industry of semiconductors, a reliability test is a key link to ensure the stability and reliability of a product process. The process usually relies on various test structures designed on a wafer to evaluate and verify the performance under different conditions. A breakdown voltage (or a resistance) is one of the important indexes to measure the insulation performance of a dielectric layer, and is crucial for evaluating the voltage endurance capability of semiconductor devices.

In related breakdown voltage test structure design, metal layer groups on upper and lower sides of the dielectric layer are usually designed independently, and in order to meet the test requirement, these metal layer groups (that is, the test structures) will occupy a certain placement area. However, with the continuous progress of a semiconductor manufacturing technology, the structure on the wafer is more and more complicated. Most of the test structures are placed in a scribe line between two adjacent chips on the wafer, and are used as monitoring structures of the manufacturing process. The positions of the test structures greatly limit the placement area and quantity of the test structures with the same test type. Meanwhile, the alignment problems in the manufacturing process, such as an alignment deviation between upper and lower metal layers and a middle through hole or between different photoetching layers, that is, overlay shift, have a significant influence on the test result. The shift not only may lead to the inaccurate test result of the breakdown voltage or resistance, but also may affect the performance and reliability of the whole semiconductor device.

At present, the test structure arranged in the same direction as the metal layer shows singularity when detecting the overlay shift direction, that is, only the shift in a specific direction can be detected. To comprehensively evaluate the shift, it is usually necessary to design a plurality of test structures in different directions, which undoubtedly increases the complexity of the test and the occupation of the wafer area, and also affects the efficiency.

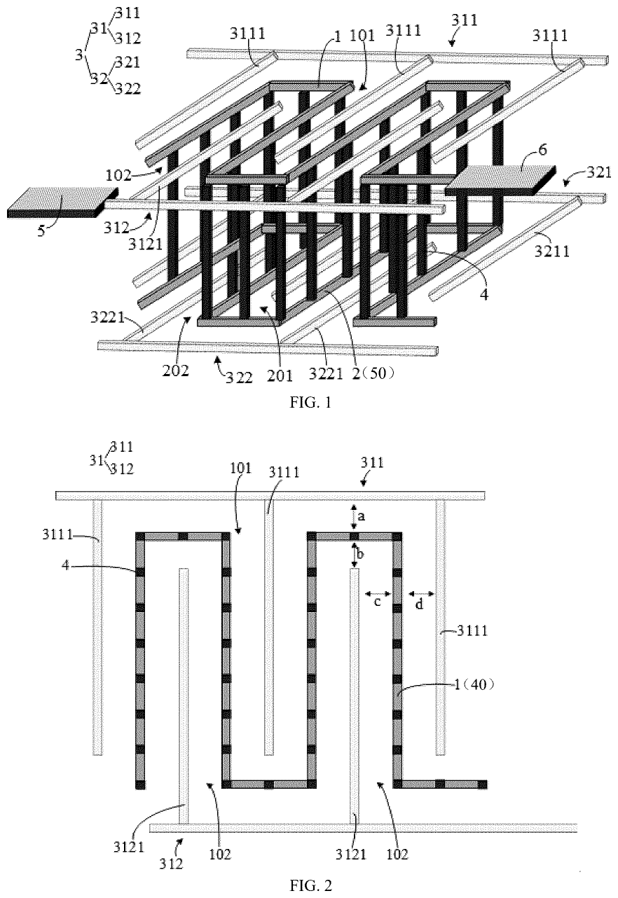

Based on this, an embodiment of the present disclosure provides a semiconductor test structure. As shown in FIG. 1 and FIG. 15, the test structure includes a first metal layer to be tested 10, a second metal layer to be tested 20, a conductive test structure 3, a first test pad 5 and a second test pad 6, where
the first metal layer to be tested 10 and the second metal layer to be tested 20 are distributed in a stacked manner, an interlayer dielectric layer 30 is filled between the first metal layer to be tested 10 and the second metal layer to be tested 20, the first metal layer to be tested 10 includes a first metal line 1 to be tested with an equal line width, and the second metal layer to be tested 20 includes a second metal line 2 to be tested with an equal line width;
the conductive test structure 3 includes a first conductive test portion 31 and/or a second conductive test portion 32, the first conductive test portion 31 and the first metal layer to be tested 10 are distributed on a same layer, the second conductive test portion 32 and the second metal layer to be tested 20 are distributed on a same layer, the first conductive test portion 31 has an equal line width everywhere, the second conductive test portion 32 also has an equal line width everywhere, a distance between the first conductive test portion 31 and the first metal line 1 to be tested is equal everywhere, and a distance between the second conductive test portion 32 and the second metal line 2 to be tested is equal everywhere;
the first metal line 1 to be tested and the second metal line 2 to be tested are connected through a plurality of via holes 4, and each of the plurality of via holes 4 penetrates through the interlayer dielectric layer 30;
the first test pad 5 is connected to the first conductive test portion 31 or the second conductive test portion 32; and
the second test pad 6 is connected to the first metal line 1 to be tested or the second metal line 2 to be tested.

According to the semiconductor test structure provided by the present disclosure, voltages can be respectively applied to the first test pad 5 and the second test pad 6, and the breakdown voltage between the conductive test structure 3 and the first metal line 1 to be tested or the second metal line 2 to be tested is detected; or a preset current is applied to flow between the first test pad 5 and the second test pad 6, the resistance between the conductive test structure 3 and the first metal line 1 to be tested or the second metal line 2 to be tested is measured, the breakdown voltage or the resistance is compared with the preset voltage value or the preset resistance value, it is inferred that there is the shift phenomenon between the first metal line 1 to be tested and the second metal line 2 to be tested when the breakdown voltage or the resistance exceeds the preset deviation range of the preset voltage value or the preset resistance value, and the shift direction between the second metal line 2 to be tested and the first metal line 1 to be tested can be further determined through sectioning. That is, in the present disclosure, through one semiconductor test structure, whether a shift phenomenon is present between upper and lower layers of metal lines can be detected, and the specific direction of shift is determined, so that data support is provided for the improvement of the semiconductor process, and it is beneficial to improve the reliability of the process. Due to the limited placement area of the test structure (Testkey), the number of the semiconductor test structures that can be placed in the present disclosure is reduced. Compared with the existing solution of respectively detecting the shift (overlay shift) in two different directions by placing two different test structures, the present disclosure provides a solution of detecting two directions simultaneously by using one test structure, so that the placement area of the semiconductor test structure can be saved, the manufacturing cost can be reduced, the test time and the number of test times can be saved, and the test efficiency can be improved. In addition, when the breakdown voltage or the resistance does not exceed the preset deviation range of the preset voltage value or the preset resistance value, it can be directly determined that the shift phenomenon is not present between the first metal line 1 to be tested and the second metal line 2 to be tested, sectioning is not required, and the test efficiency is high.

Each part of the semiconductor test structure of the present disclosure and the specific details thereof will be described in detail below:
the first metal layer to be tested 10 and the second metal layer to be tested 20 can be distributed in a stacked manner, and in some embodiments of the present disclosure, the interlayer dielectric layer 30 is filled between the first metal layer to be tested 10 and the second metal layer to be tested 20. Continuously referring to FIG. 1, the first metal layer to be tested 10 may include a first metal line 1 to be tested with an equal line width, and the second metal layer to be tested 20 may include a second metal line 2 to be tested with an equal line width. That is, the first metal line 1 to be tested in the first metal layer to be tested 10 has an equal line width everywhere, and the second metal line 2 to be tested in the second metal layer to be tested 20 has an equal line width everywhere. The line widths of the first metal line 1 to be tested and the second metal line 2 to be tested may be the same or may be different, which is not particularly limited here.

In one exemplary embodiment of the present disclosure, the line widths of the first metal line 1 to be tested and the second metal line 2 to be tested follow a min design rule, that is, the line widths of the first metal line 1 to be tested and the second metal line 2 to be tested are the minimum line widths based on that the conductive characteristic is met.

A material of the first metal line 1 to be tested may be a material with high conductivity, for example, the material may be copper, aluminum, tungsten or titanium nitride, of course, may be other materials with high conductivity, which will not be listed one by one here. A material of the interlayer dielectric layer 30 may be an insulating material, for example, the material may be silicon oxide or silicon nitride. A material of the second metal line 2 to be tested may be a material with high conductivity, for example, the material may be copper, aluminum, tungsten or titanium nitride, of course, may be other materials with high conductivity, which will not be listed one by one here.

In some embodiments of the present disclosure, as shown in FIG. 2, the first metal line 1 to be tested may have a serpentine structure, an S-shaped structure or a linear structure; when the first metal line 1 to be tested has the serpentine structure, for the convenience to distinguish the first metal line 1 to be tested and the second metal line 2 to be tested, the serpentine structure corresponding to the first metal line 1 to be tested may serve as a first serpentine structure 40; one side of the first serpentine structure 40 is provided with a plurality of first grooves 101 spaced apart, and another side of the first serpentine structure 40 is provided with a plurality of second grooves 102 spaced apart; and the plurality of first grooves 101 and the plurality of second grooves 102 are distributed alternately. It should be noted that the first grooves 101 and the second grooves 102 have groove-shaped structures defined by the structure of the first serpentine structure 40.

Continuously referring to FIG. 1, the second metal line 2 to be tested may also have a serpentine structure, an S-shaped structure or a linear structure; and in the present disclosure, the setting details and the cooperative relationship with other structures are described by taking the case where the second metal line 2 to be tested has the serpentine structure as an example. For the convenience of distinguishing, the serpentine structure corresponding to the second metal line 2 to be tested may serve as a second serpentine structure 50; one side of the second serpentine structure 50 is provided with a plurality of third grooves 201 spaced apart, and another side of the second serpentine structure 50 is provided with a plurality of fourth grooves 202 spaced apart; and the plurality of third grooves 201 and the plurality of fourth grooves 202 are distributed alternately. It should be noted that the third grooves 201 and the fourth grooves 202 have groove-shaped structures defined by the structure of the second serpentine structure 50.

In one exemplary embodiment of the present disclosure, continuously referring to FIG. 1, and FIG. 2, the first metal line 1 to be tested and the second metal line 2 to be tested can be connected through a plurality of via holes 4, the via holes 4 can penetrate through the interlayer dielectric layer 30, and the via holes 4 are filled with conductive materials, that is, the first metal line 1 to be tested can communicate with the second metal line 2 to be tested through the conductive materials. The line widths of the via holes 4 follow a min design rule, that is, the line widths of the via holes 4 are the minimum line widths based on that the conductivity thereof is met.

In some embodiments of the present disclosure, as shown in FIG. 2, and FIG. 3, the conductive test structure 3 may include a first conductive test portion 31, and the first conductive test portion 31 and the first metal layer to be tested 10 are distributed on a same layer. The first conductive test portion 31 has an equal line width everywhere, that is, each area in the first conductive test portion 31 has an equal line width; and a distance between the first conductive test portion 31 and the first metal line 1 to be tested is equal everywhere (that is, a=b=c=d in FIG. 2). It should be noted that the line width of the first conductive test portion 31 follows a min design rule, that is, the line width of the first conductive test portion 31 is a minimum line width based on that the conductivity thereof is met. The distance between the first conductive test portion 31 and the first metal line 1 to be tested is a minimum distance that can ensure that the first conductive test portion and the first metal line to be tested will not be conducted or coupled.

A shape of the first conductive test portion 31 is matched that with that of the first metal line 1 to be tested in the first metal layer to be tested 10. For example, when the first metal line 1 to be tested is linear, the first conductive test portion 31 is also linear; and when the first metal line 1 to be tested is serpentine or S-shaped, the first conductive test portion 31 has a comb-shaped structure (as shown in FIG. 1 to FIG. 3).

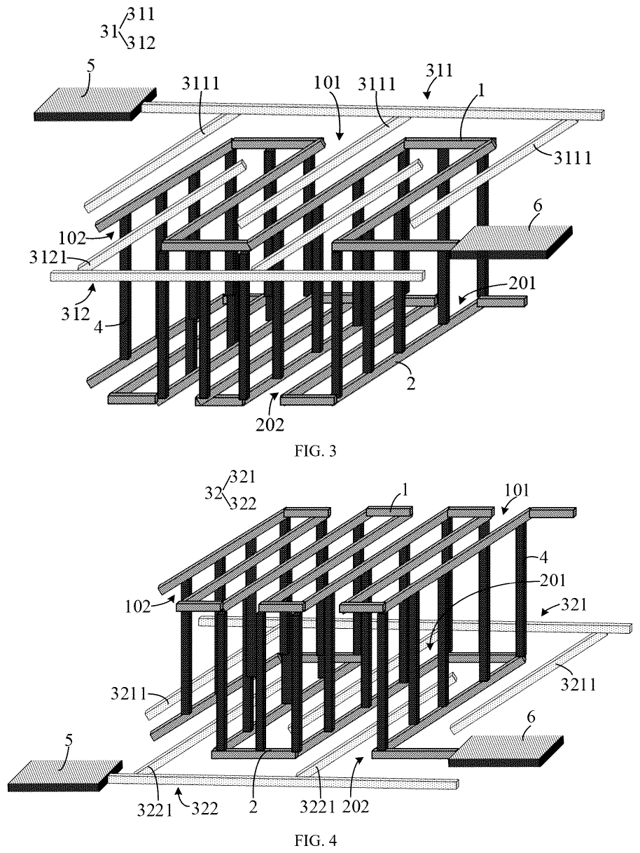

In some other embodiments of the present disclosure, as shown in FIG. 4, the conductive test structure 3 may include a second conductive test portion 32, and the second conductive test portion 32 and the second metal layer to be tested 20 are distributed on a same layer. The second conductive test portion 32 has an equal line width everywhere, that is, each area in the second conductive test portion 32 has an equal line width. A distance between the second conductive test portion 32 and the second metal line 2 to be tested is equal everywhere. It should be noted that the line width of the second conductive test portion 32 follows a min design rule, that is, the line width of the second conductive test portion 32 is a minimum line width based on that the conductivity thereof is met. The distance between the second conductive test portion 32 and the second metal line 2 to be tested is a minimum distance that can ensure that the second conductive test portion and the second metal line to be tested will not be conducted or coupled.

A shape of the second conductive test portion 32 is matched that with that of the second metal line 2 to be tested in the second metal layer to be tested 20. For example, when the second metal line 2 to be tested is linear, the second conductive test portion 32 is also linear; and when the second metal line 2 to be tested is serpentine or S-shaped, the second conductive test portion 32 has a comb-shaped structure (as shown in FIG. 1 to FIG. 4).

In some other embodiments of the present disclosure, continuously referring to FIG. 1, the conductive test structure 3 may include a first conductive test portion 31 and a second conductive test portion 32, where the first conductive test portion 31 and the first metal layer to be tested 10 are distributed on a same layer, and the second conductive test portion 32 and the second metal layer to be tested 20 are distributed on a same layer. The first conductive test portion 31 has an equal line width everywhere, and the second conductive test portion 32 also has an equal line width everywhere; and a distance between the first conductive test portion 31 and the first metal line 1 to be tested is equal everywhere, and a distance between the second conductive test portion 32 and the second metal line 2 to be tested is equal everywhere.

In one exemplary embodiment of the present disclosure, continuously referring to FIG. 1 to FIG. 3, when the first metal line 1 to be tested has a serpentine structure, the first conductive test portion 31 may include a first comb-shaped structure 311 and a second comb-shaped structure 312, where the first comb-shaped structure 311 is arranged on one side of the first serpentine structure 40, the number of comb teeth 3111 of the first comb-shaped structure is matched with the number of the first grooves 101, each of the comb teeth 3111 of the first comb-shaped structure is correspondingly inserted into a different first groove 101, and distances between all areas of the comb teeth 3111 of the first comb-shaped structure and the surrounding first metal line 1 to be tested are equal. The second comb-shaped structure 312 is arranged on another side of the first serpentine structure 40, the number of comb teeth 3121 of the second comb-shaped structure is matched with the number of the second grooves 102, each of the comb teeth 3121 of the second comb-shaped structure are correspondingly inserted into a different second groove 102, and distances between all areas of the comb teeth 3121 of the second comb-shaped structure and the surrounding first metal line 1 to be tested are equal.

Continuously referring to FIG. 1 to FIG. 4, when the second metal line 2 to be tested has a serpentine structure, the second conductive test portion 32 may include a third comb-shaped structure 321 and a fourth comb-shaped structure 322, where the third comb-shaped structure 321 is arranged on one side of the second serpentine structure 50, the number of comb teeth 3211 of the third comb-shaped structure is matched with the number of the third grooves 201, each of the comb teeth 3211 of the third comb-shaped structure is correspondingly inserted into a different third groove 201, and distances between all areas of the comb teeth 3211 of the third comb-shaped structure and the surrounding second metal line 2 to be tested are equal. The fourth comb-shaped structure 322 is arranged on another side of the second serpentine structure 50, the number of comb teeth 3221 of the fourth comb-shaped structure is matched with the number of the four grooves 202, each of the comb teeth 3221 of the fourth comb-shaped structure is correspondingly inserted into a different fourth groove 202, and distances between all areas of the comb teeth 3221 of the fourth comb-shaped structure and the surrounding second metal line 2 to be tested are equal.

Continuously referring to FIG. 1, FIG. 3, and FIG. 4, the first test pad 5 may be sheet-like and made of a conductive material, for example, copper. The first test pad 5 may be connected to the first conductive test portion 31 or the second conductive test portion 32. Continuously referring to FIG. 3, when the conductive test structure 3 only includes the first conductive test portion 31, the first serpentine structure 40 and the second serpentine structure 50 are connected through a plurality of via holes 4, the first test pad 5 is connected to the first conductive test portion 31, for example, the first test pad 5 may be connected to the first comb-shaped structure 311 in the first conductive test portion 31 or the second comb-shaped structure 312 in the first conductive test portion 31, and the connection area between the first test pad 5 and the first conductive test portion 31 is not particularly limited here.

Continuously referring to FIG. 4, when the conductive test structure 3 only includes the second conductive test portion 32, the first serpentine structure 40 and the second serpentine structure 50 are connected through a plurality of via holes 4, the first test pad 5 is connected to the second conductive test portion 32, for example, the first test pad 5 may be connected to the third comb-shaped structure 321 in the second conductive test portion 32 or the fourth comb-shaped structure 322 in the second conductive test portion 32, and the connection area between the first test pad 5 and the second conductive test portion 32 is not particularly limited here.

When the conductive test structure 3 includes both the first conductive portion 31 and the second conductive test portion 32, the first serpentine structure 40 and the second serpentine structure 50 may be connected through a plurality of via holes 4. The first test pad 5 may be connected to the first conductive test portion 31 or the second conductive test portion 32. For example, the first test pad 5 may be connected to any one of the first comb-shaped structure 311, the second comb-shaped structure 312, the third comb-shaped structure 321 and the fourth comb-shaped structure 322.

Continuously referring to FIG. 1, FIG. 3, and FIG. 4, the second test pad 6 may be sheet-like and made of a conductive material, for example, copper. The second test pad 6 may be connected to an end part of the first metal line 1 to be tested or an end part of the second metal line 2 to be tested. For example, the second test pad 6 may be connected to the first serpentine structure 40 or the second serpentine structure 50. Voltages may be respectively applied to the first test pad 5 and the second test pad 6, and the breakdown voltage between the conductive test structure 3 and the first metal line 1 to be tested or the second metal line 2 to be tested is detected; or a preset current is applied to flow between the first test pad 5 and the second test pad 6, the resistance between the conductive test structure 3 and the first metal line 1 to be tested or the second metal line 2 to be tested is measured, the breakdown voltage or the resistance is compared with the preset voltage value or the preset resistance value, it is inferred that there is the shift phenomenon between the first metal line 1 to be tested and the second metal line 2 to be tested when the breakdown voltage or the resistance exceeds the preset deviation range of the preset voltage value or the preset resistance value, and the shift direction between the second metal line 2 to be tested and the first metal line 1 to be tested can be further determined through sectioning.

It should be noted that when the first test pad 5 is connected to the first comb-shaped structure 311 or the second comb-shaped structure 312, the finally detected breakdown voltage or resistance is the breakdown voltage or resistance corresponding to the first metal line 1 to be tested; and when the first test pad 5 is connected to the third comb-shaped structure 321 or the fourth comb-shaped structure 322, the finally detected breakdown voltage or resistance is the breakdown voltage or resistance corresponding to the second metal line 2 to be tested.

In one exemplary embodiment of the present disclosure, when the line width of the first metal line 1 to be tested is not equal to that of the second metal line 2 to be tested, and the conductive test structure 3 only includes the first conductive test portion 31 or only includes the second conductive test portion 32, the line width of the first metal line 1 to be tested is equal to that of the corresponding first conductive test portion 31, or the line width of the second conductive test portion 32 is equal to that of the corresponding second metal line 2 to be tested.

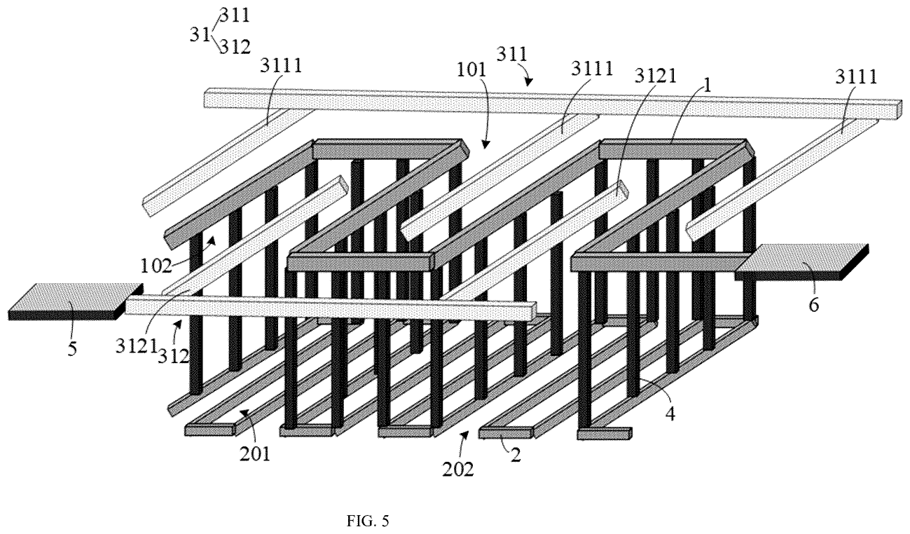

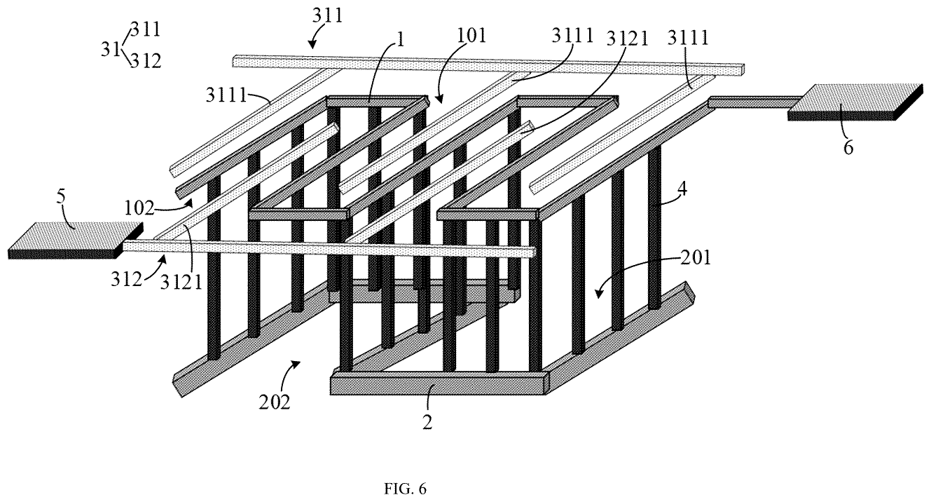

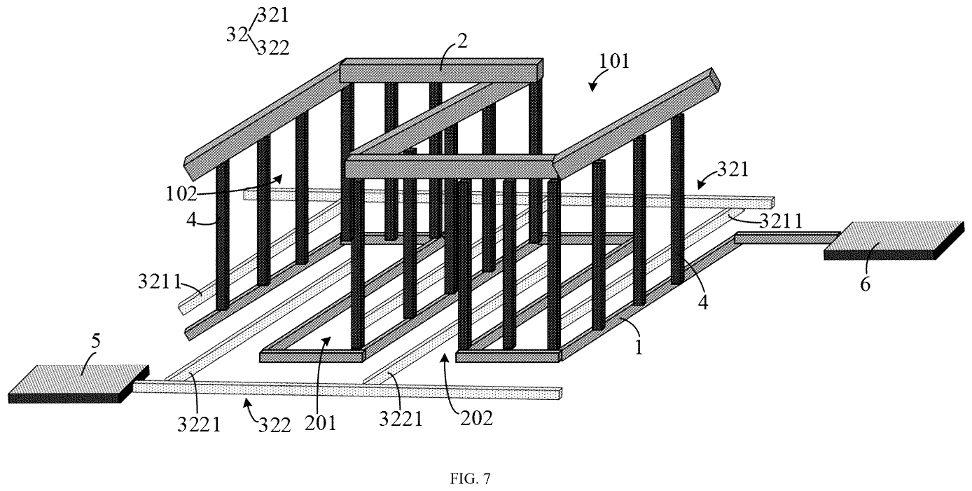

In some embodiments of the present disclosure, as shown in FIG. 5, the conductive test structure 2 only includes the first conductive test portion 31, the line width of the first metal line 1 to be tested is greater than that of the second metal line 2 to be tested, and the line width of the first conductive test portion 31 is equal to that of the first metal line 1 to be tested. In some embodiments of the present disclosure, as shown in FIG. 6, the conductive test structure 3 only includes the first conductive test portion 31, the line width of the first metal line 1 to be tested is less than that of the second metal line 2 to be tested, and the line width of the first conductive test portion 31 is equal to that of the first metal line 1 to be tested. In some embodiments of the present disclosure, as shown in FIG. 7, the conductive test structure 3 only includes the second conductive test portion 32, the line width of the first metal line 1 to be tested is greater than that of the second metal line 2 to be tested, and the line width of the second conductive test portion 32 is equal to that of the second metal line 2 to be tested. In some embodiments of the present disclosure, as shown in FIG. 8, the conductive test structure 3 only includes the second conductive test portion 32, the line width of the first metal line 1 to be tested is less than that of the second metal line 2 to be tested, and the line width of the second conductive test portion 32 is equal to that of the second metal line 2 to be tested.

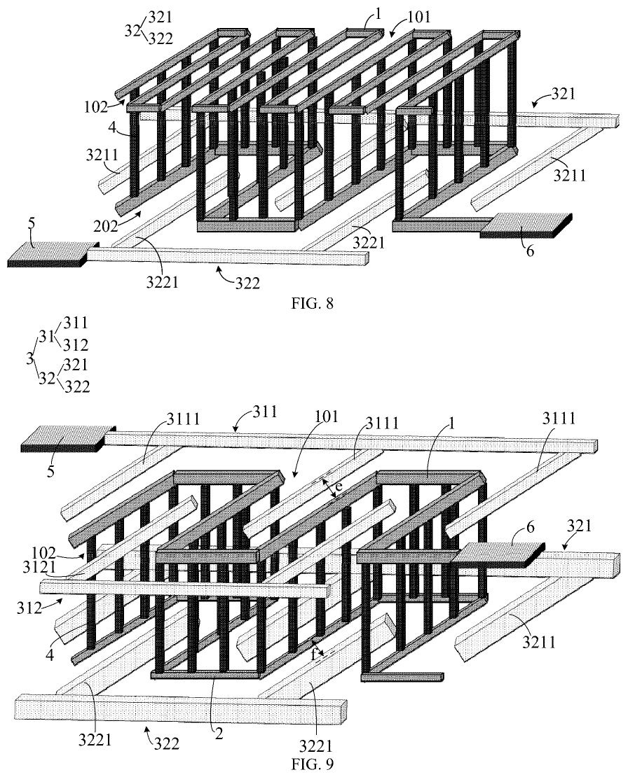

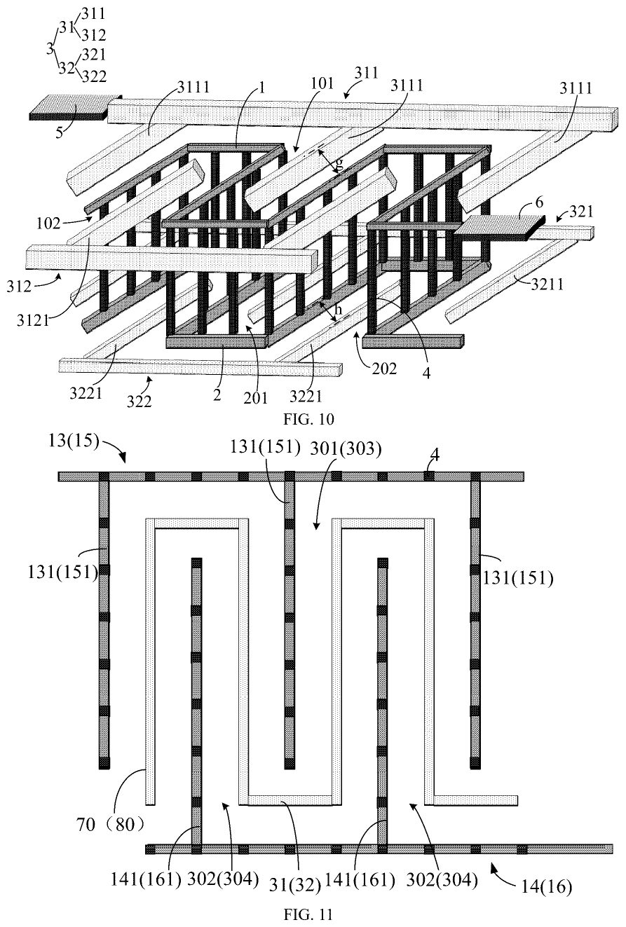

In one exemplary embodiment of the present disclosure, when the line width of the first metal line 1 to be tested is not equal to that of the second metal line 2 to be tested, and the conductive test structure 3 not only includes the first conductive test portion 31, but also includes the second conductive test portion 32, the metal line to be tested with larger line width is equal to that of the corresponding conductive test portion, and the metal line to be tested with smaller line width is not equal to that of the corresponding conductive test portion. As shown in FIG. 9, when the line width of the first metal line 1 to be tested is greater than that of the second metal line 2 to be tested, the line width of the first conductive test portion 31 is equal to that of the first metal line 1 to be tested, the line width of the second conductive test portion 32 is greater than that of the second metal line 2 to be tested, and the line width of the second conductive test portion 32 is greater than that of the first conductive test portion 31. Furthermore, the line width of the second conductive test portion 32 is: twice a distance (that is, e in FIG. 9) between a center line of the first conductive test portion 31 and a center line of the first metal line 1 to be tested, minus a distance (that is, f in FIG. 9) between a center line of the second conductive test portion 32 and a center line of the second metal line 2 to be tested, and further minus the line width of the second metal line 2 to be tested. As shown in FIG. 10, when the line width of the first metal line 1 to be tested is less than that of the second metal line 2 to be tested, the line width of the second conductive test portion 32 is equal to that of the second metal line 2 to be tested, the line width of the first conductive test portion 31 is greater than that of the first metal line 1 to be tested, and the line width of the first conductive test portion 31 is greater than that of the second conductive test portion 32. Furthermore, the line width of the first conductive test portion 31 is: twice a distance (that is, g in FIG. 10) between the center line of the second conductive test portion 32 and the center line of the second metal line 2 to be tested, minus a distance (that is, h in FIG. 10) between the center line of the first conductive test portion 31 and the center line of the first metal line 1 to be tested, and further minus the line width of the first metal line 1 to be tested.

In one exemplary embodiment of the present disclosure, as shown in FIG. 11, the shapes of the first metal line 1 to be tested and/or the second metal line 2 to be tested may be interchanged with the shape of the conductive test structure 3. For example, the shape of the conductive test structure 3 (for example, the first conductive test portion 31 or the second conductive test portion 32) may be a serpentine structure, and correspondingly, the shapes of the first metal line 1 to be tested and the second metal line 2 to be tested may both be comb-shaped structures.

In one exemplary embodiment of the present disclosure, the first conductive test portion 31 may have a serpentine structure, the serpentine structure corresponding to the first conductive test portion 31 may serve as a third serpentine structure 70, one side of the third serpentine structure 70 is provided with a plurality of first concave portions 301 spaced apart, another side of the third serpentine structure 70 is provided with a plurality of second concave portions 302 spaced apart, and the first concave portions 301 and the second concave portions 302 are distributed alternately. It should be noted that the first concave portions 301 and the second concave portions 302 have groove-shaped structures defined by the structure of the third serpentine structure 70.

In some embodiments of the present disclosure, continuously referring to FIG. 11, when the first conductive test portion 31 has a serpentine structure, the first metal line 1 to be tested in the first metal layer to be tested 10 includes two metal lines, and both the two metal lines have comb-shaped structures. For the convenience of distinguishing, the first metal line 1 to be tested may be defined as including a fifth comb-shaped structure 13 and a sixth comb-shaped structure 14, where the fifth comb-shaped structure 13 is arranged on one side of the third serpentine structure 70, the number of comb teeth 131 of the fifth comb-shaped structure is matched with the number of the first concave portions 301, each of the comb teeth 131 of the fifth comb-shaped structure is correspondingly inserted into a different first concave portion 301, and distances between all areas of the comb teeth 131 of the fifth comb-shaped structure and the surrounding first conductive test portion 31 are equal; and the sixth comb-shaped structure 14 is arranged on another side of the third serpentine structure 70, the number of comb teeth 141 of the sixth comb-shaped structure is matched with the number of the second concave portions 302, each of the comb teeth 141 of the sixth comb-shaped structure is correspondingly inserted into a different second concave portion 302, and distances between all areas of the comb teeth 141 of the sixth comb-shaped structure and the surrounding first conductive test portion 31 are equal.

In some embodiments of the present disclosure, continuously referring to FIG. 11, the second conductive test portion 32 may also have a serpentine structure, the serpentine structure corresponding to the second conductive test portion 32 may serve as a fourth serpentine structure 80, one side of the fourth serpentine structure 80 is provided with a plurality of third concave portions 303 spaced apart, another side of the fourth serpentine structure 80 is provided with a plurality of fourth concave portions 304 spaced apart, and the plurality of third concave portions 303 and the plurality of fourth concave portions 304 are distributed alternately. It should be noted that the third concave portions 303 and the fourth concave portions 304 have groove-shaped structures defined by the structure of the fourth serpentine structure 80.

In some embodiments of the present disclosure, when the second conductive test portion 32 has a serpentine structure, the second metal line 2 to be tested in the first metal layer to be tested 10 includes two metal lines, and both the two metal lines have comb-shaped structures. For the convenience of distinguishing, the second metal line 2 to be tested may be defined as including a seventh comb-shaped structure 15 and an eighth comb-shaped structure 16, where the seventh comb-shaped structure 15 is arranged on one side of the third serpentine structure 70, the number of comb teeth 151 of the seventh comb-shaped structure is matched with the number of the third concave portions 303, each of the comb teeth 151 of the seventh comb-shaped structure is correspondingly inserted into a different third concave portion 303, and distances between all areas of the comb teeth 151 of the seventh comb-shaped structure and the surrounding second conductive test portion 32 are equal; and the eighth comb-shaped structure 16 is arranged on another side of the third serpentine structure 70, the number of comb teeth 161 of the eighth comb-shaped structure is matched with the number of the fourth concave portions 304, each of the comb teeth 161 of the eighth comb-shaped structure are correspondingly inserted into a different fourth concave portion 304, and distances between all areas of the comb teeth 161 of the eighth comb-shaped structure and the surrounding second conductive test portion 32 are equal.

In some embodiments of the present disclosure, when the conductive test structure 3 only includes the first conductive test portion 31, and the first test pad 5 is connected to the first conductive test portion 31. At this time, the fifth comb-shaped structure 13 and the seventh comb-shaped structure 15 are connected through a plurality of via holes 4, the sixth comb-shaped structure 14 and the eighth comb-shaped structure 16 are connected through a plurality of via holes 4, and the second test pad 6 is connected to any one of the fifth comb-shaped structure 13, the sixth comb-shaped structure 14, the seventh comb-shaped structure 15, or the eighth comb-shaped structure 16.

In some embodiments of the present disclosure, when the conductive test structure 3 only includes a second conductive test portion 32, and the first test pad 5 is connected to the second conductive test portion 32. At this time, the fifth comb-shaped structure 13 and the seventh comb-shaped structure 15 are connected through a plurality of via holes 4, the sixth comb-shaped structure 14 and the eighth comb-shaped structure 16 are connected through a plurality of via holes 4, and the second test pad 6 is connected to any one of the fifth comb-shaped structure 13, the sixth comb-shaped structure 14, the seventh comb-shaped structure 15, or the eighth comb-shaped structure 16.

In some embodiments of the present disclosure, when the conductive test structure 3 includes both the first conductive test portion 31 and the second conductive test portion 32, the first test pad 5 is connected to the first conductive test portion 31 or the second conductive test portion 32. At this time, the fifth comb-shaped structure 13 and the seventh comb-shaped structure 15 are connected through a plurality of via holes 4, the sixth comb-shaped structure 14 and the eighth comb-shaped structure 16 are connected through a plurality of via holes 4, and the second test pad 6 is connected to any one of the fifth comb-shaped structure 13, the sixth comb-shaped structure 14, the seventh comb-shaped structure 15, or the eighth comb-shaped structure 16.

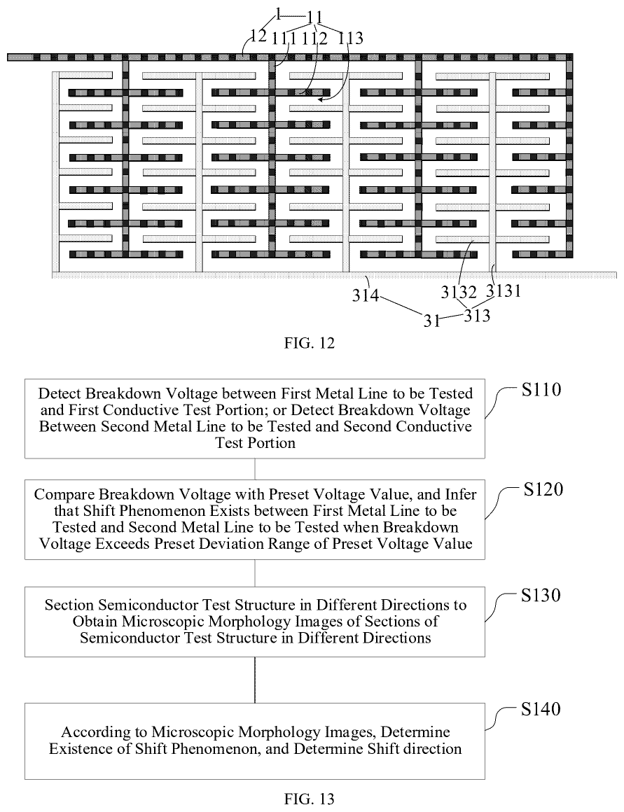

In one exemplary embodiment of the present disclosure, as shown in FIG. 12, the first metal line 1 to be tested may include a plurality of first comb-type structures 11 communicating with each other, each of the plurality of first comb-type structures 11 includes a first comb spine 111 and a plurality of first comb teeth 112 located on one side or two sides of the first comb spine 111, the first comb teeth 112 may be distributed in parallel, and a plurality of first tooth gaps 113 spaced apart in a length direction of the first comb spine 111 are surrounded by the plurality of first comb teeth 112 and the first comb spine 111. End parts of a plurality of first comb spines 111 in the plurality of first comb-type structures 11 located on the same side may be connected through one or more first connecting lines 12.

The second metal line 2 to be tested may include a plurality of second comb-type structures 90 communicating with each other, each of the plurality of second comb-type structures 90 includes a second comb spine 91 and a plurality of second comb teeth 92 located on one side or two sides of the second comb spine 91, the second comb teeth 92 may be distributed in parallel, and a plurality of second tooth gaps 93 spaced apart in a length direction of the second comb spine 91 are surrounded by the plurality of second comb teeth 92 and the second comb spine 91. End parts of a plurality of second combs spine 91 in the plurality of second comb-type structures 90 located on the same side may be connected through one or more second connecting lines 901.

Continuously referring to FIG. 12, the first conductive test portion 31 may include a plurality of third comb-type structures 313 connected with each other, each of the plurality of third comb-type structures 313 includes a third comb spine 3131 and a plurality of third comb teeth 3132 located on one side or two sides of the third comb spine 3131, and the plurality of third comb teeth 3132 may be spaced apart in a length direction of the third spine 3131. Each of the third comb teeth 3132 in each of the third comb-type structures 313 may be correspondingly inserted into a different first tooth gap 113. End parts of a plurality of third comb spines 3131 in the plurality of third comb-type structures 313 located on the same side may be connected through one or more third connecting lines 314, and the one or more third connecting lines 314 and the one or more first connecting lines 12 are located on different sides.

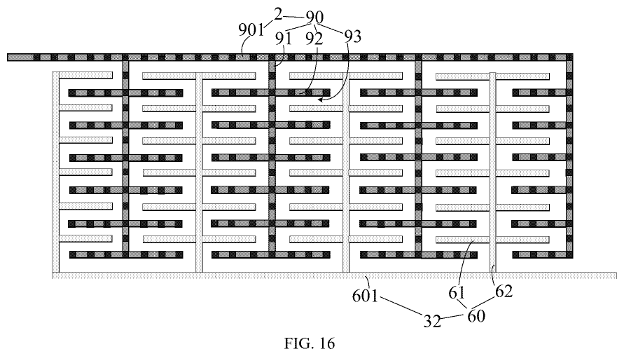

Referring to FIG. 16, the second conductive test portion 32 may include a plurality of fourth comb-type structures 60 connected with each other, each of the plurality of fourth comb-type structures 60 includes a fourth comb spine 62 and a plurality of fourth comb teeth 61 located on one side or two sides of the fourth comb spine 62, and the plurality of fourth comb teeth 61 may be spaced apart in a length direction of the fourth comb spine 62. Each of the fourth comb teeth 61 in each of the fourth comb-type structures 60 may be correspondingly inserted into a different second tooth gap 93. End parts of a plurality of fourth comb spines 62 in the plurality of fourth comb-type structures 60 located on the same side may be connected through one or more fourth connecting lines 601, and the one or more fourth connecting lines 601 and the one or more second connecting lines 901 are located on different sides.

In one exemplary embodiment of the present disclosure, the first comb-type structure 11 and the second comb-type structure 90 may be connected through a plurality of via holes 4. When the conductive test structure 3 only includes the first conductive test portion 31, the first test pad 5 is connected to the first conductive test portion 31. For example, the first test pad 5 is connected to the third comb-type structures 313 in the first conductive test portion 31. For example, the first test pad 5 is connected to the one or more third connecting lines 314 for connecting each of the third comb-type structures 313 in the first conductive test portion 31.

When the conductive test structure 3 only includes the second conductive test portion 32, the first test pad 5 is connected to the second conductive test portion 32. For example, the first test pad 5 is connected to the fourth comb-type structures 60 in the second conductive test portion 32. For example, the first test pad 5 is connected to the one or more fourth connecting lines for connecting each of the fourth comb-type structures 60 in the second conductive test portion 32.

In one exemplary embodiment of the present disclosure, the conductive test structure 3 not only includes the first conductive test portion 31, but also includes the second conductive test portion 32. Each of the plurality of the first comb-type structures 11 and a corresponding second comb-type structure 90 are connected through a plurality of via holes 4. At this time, the first test pad 5 may be connected to the third comb-type structures 313, or the first test pad 5 may be connected to the fourth comb-type structures 60.

The second test pad 6 may be connected to the plurality of first comb-type structures 11 or the plurality of second comb-type structures 90. For example, the second test pad 6 may be connected to the one or more first connecting lines 12 of each first comb spine 111 connected to each of the plurality of first comb-type structures 11, or the second test pad 6 may be connected to the one or more second connecting lines 901 connected to each second comb spine 91 of each of the second comb-type structures 90.

The present disclosure further provides a test method for interlayer overlay shift of metal layers. The test method adopts the semiconductor test structure in any one of the above embodiments for testing. As shown in FIG. 13, the test method may include step S110 to step S140.

Step S110: a breakdown voltage between a first metal line to be tested and a first conductive test portion is detected; or a breakdown voltage between a second metal line to be tested and a second conductive test portion is detected.

In some embodiments of the present disclosure, the detection process for detecting a breakdown voltage between a first metal line 1 to be tested and a first conductive test portion 31 includes: a first voltage and a second voltage are respectively applied to a first test pad 5 and a second test pad 6 connected to the first conductive test portion 31. A voltage value of the first voltage is different from that of the second voltage. For example, the first voltage may be a low voltage, and the second voltage may be a variable voltage value. The voltage value corresponding to the second voltage may be gradually increased to the second test pad 6 until the first metal line 1 to be tested and the first conductive test portion 31 are broken down; and when the first metal line 1 to be tested and the first conductive test portion 31 are broken down, a voltage difference between the first voltage and the second voltage serves as the breakdown voltage.

In some embodiments of the present disclosure, the detection process for detecting a breakdown voltage between a second metal line 2 to be tested and a second conductive test portion 32 includes: a first voltage and a second voltage are respectively applied to a first test pad 5 and a second test pad 6 connected to the second conductive test portion 32. A voltage value of the first voltage is different from that of the second voltage. For example, the first voltage may be a low voltage, and the second voltage may be a variable voltage value. The voltage value corresponding to the second voltage may be gradually increased to the second test pad 6 until the second metal line 2 to be tested and the second conductive test portion 32 are broken down; and when the second metal line 2 to be tested and the second conductive test portion 32 are broken down, a voltage difference between the first voltage and the second voltage serves as the breakdown voltage.

Step S120: the breakdown voltage is compared with a preset voltage value, and it is inferred that a shift phenomenon exists between the first metal line to be tested and the second metal line to be tested when the breakdown voltage exceeds a preset deviation range of the preset voltage value.

A preset voltage value may be a theoretical value or an empirical value of the breakdown voltage that is calculated and estimated according to the conditions of the manufacturing process when a shift phenomenon is not present between the first metal line 1 to be tested and the second metal line 2 to be tested. A preset deviation range of the preset voltage value may be a deviation range of the breakdown voltage that does not affect the electric performance of the first metal line 1 to be tested and the second metal line 2 to be tested, that is, the preset deviation range of the preset voltage value is an allowable range in which the actual measured value of the breakdown voltage deviates from the theoretical value or the empirical value of the breakdown voltage.

Step S130: the semiconductor test structure is sectioned in different directions to obtain microscopic morphology images of sections of the semiconductor test structure in different directions.

The microscopic morphology images may be scanning electron microscope images of the semiconductor test structure.

Step S140: according to the microscopic morphology images, the existence of the shift phenomenon is determined, and a shift direction is determined.

The existence of shift between the first metal layer to be tested 10 and the second metal layer to be tested 20 in the semiconductor test structure can be observed through the scanning electron microscope images of the semiconductor test structure in different directions; and if it is found that the shift is present between the first metal layer to be tested 10 and the second metal layer to be tested 20 through microscopic morphology analysis, it is indicated that a process for forming the first metal layer to be tested 10 and the second metal layer to be tested 20 has defects and is required to be improved. That is, the design of the semiconductor test structure and the test method for the interlayer overlay shift of the metal layers provided by the present disclosure can provide data support for the improvement of the process, thereby helping to increase the yield of products and improve the reliability of the products.

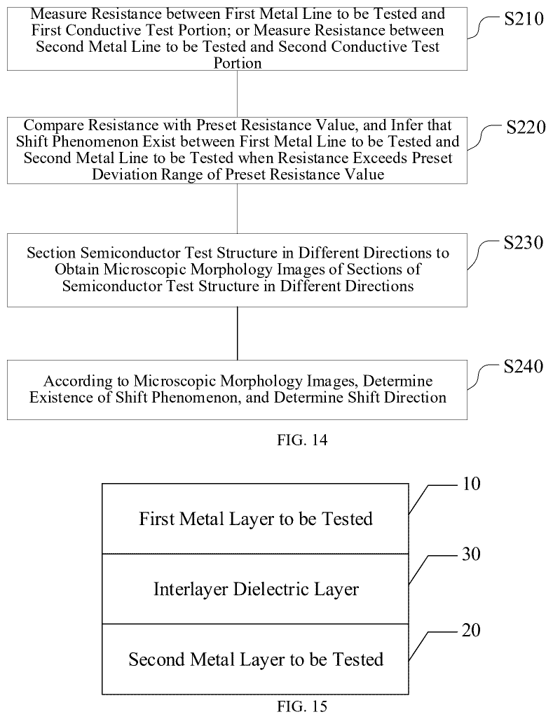

The present disclosure further provides a test method for interlayer overlay shift of metal layers. The test method adopts the semiconductor test structure in any one of the above embodiments for testing. As shown in FIG. 14, the test method may include step S210 to step S240.

Step S210: a resistance between a first metal line to be tested and a first conductive test portion is measured; or a resistance between a second metal line to be tested and a second conductive test portion is measured.

In some embodiments of the present disclosure, the measurement process for measuring the resistance between the first metal line 1 to be tested and the first conductive test portion 31 includes: a preset current is applied to flow between a first test pad 5 and a second test pad 6 connected to the first conductive test portion 31, and a voltage difference between the first metal line 1 to be tested and the first conductive test portion 31 is measured, where the resistance is equal to a ratio of the voltage difference to the current. It should be noted that the preset current may be any current value, but preset currents respectively applied to the first test pad 5 and the second test pad 6 are equal. Correspondingly, the measurement process for measuring the resistance between the second metal line 2 to be tested and the second conductive test portion 32 includes: a preset current is applied to flow between the first test pad 5 and the second test pad 6 connected to the second conductive test portion 32, and a voltage difference between the second metal line 2 to be tested and the second conductive test portion 32 is measured, where the resistance is equal to a ratio of the voltage difference to the current.

Step S220: the resistance is compared with a preset resistance value, and it is inferred that a shift phenomenon exists between the first metal line to be tested and the second metal line to be tested when the resistance exceeds a deviation range of the preset resistance value.

The preset resistance value may be a theoretical value or an empirical value of the resistance that is calculated and estimated according to the conditions of the manufacturing process when a shift phenomenon not exists between the first metal line 1 to be tested and the second metal line 2 to be tested. A preset deviation range of the preset resistance value may be a deviation of the resistance that does not affect the electric performance of the first metal line 1 to be tested and the second metal line 2 to be tested. That is, the preset deviation range of the preset resistance value is an allowable range in which the actual measured value of the resistance deviates from the theoretical value or the empirical value of the resistance.

Step S230: the semiconductor test structure is sectioned in different directions to obtain microscopic morphology images of sections of the semiconductor test structure in different directions.

Step S240: according to the microscopic morphology images, the existence of the shift phenomenon is determined, and a shift direction is determined.

The process for sectioning and determining the shift is substantially the same as that in the previous embodiment, and thus will not be elaborated herein.

According to the test method for the interlayer overlay shift of the metal layers provided by the present disclosure, voltages can be respectively applied to the first test pad 5 and the second test pad 6, and the breakdown voltage between the conductive test structure 3 and the first metal line 1 to be tested or the second metal line 2 to be tested is detected; or a preset current is applied to flow between the first test pad 5 and the second test pad 6, the resistance between the conductive test structure 3 and the first metal line 1 to be tested or the second metal line 2 to be tested is measured, the breakdown voltage or the resistance is compared with the preset voltage value or the preset resistance value, it is inferred that there is the shift phenomenon between the first metal line 1 to be tested and the second metal line 2 to be tested when the breakdown voltage or the resistance exceeds the preset deviation range of the preset voltage value or the preset resistance value, and the shift direction between the second metal line 2 to be tested and the first metal line 1 to be tested can be further determined through sectioning. That is, in the present disclosure, through one semiconductor test structure, whether a shift (overlay shift) phenomenon is present between upper and lower layers of metal lines can be detected, and the specific direction of shift is determined, so that window reference of metal layer shift (overlay shift) is provided for the improvement of a semiconductor process, the technological process is monitored, and it is beneficial to improve the reliability of the process. When the breakdown voltage or the resistance does not exceed the preset deviation range of the preset voltage value or the preset resistance value, it can be directly determined that the shift phenomenon is not present between the first metal line 1 to be tested and the second metal line 2 to be tested, sectioning is not required, and the test efficiency is high.

It should be noted that although the steps of the test method for the interlayer overlay shift of the metal layers in the present disclosure are described in the drawings in a specific order, this does not require or imply that these steps must be performed in this specific order, or that all the steps shown must be performed to achieve the desired results. Additionally or alternatively, some steps may be omitted, a plurality of steps may be combined into one step for performing, and/or one step may be decomposed into a plurality of steps for performing.

Other embodiments of the present disclosure will be apparent to those skilled in the art from consideration of the specification and practice of the present disclosure. The present disclosure is intended to cover any variations, uses, or adaptations of the present disclosure following the general principles thereof and including common knowledge or commonly used technical measures which are not disclosed herein. The specification and embodiments are to be considered as exemplary only, and the true scope and spirit of the present disclosure are indicated by the appended claims.

What is claimed is:

1. A semiconductor test structure, comprising:
a first metal layer to be tested and a second metal layer to be tested that are distributed in a stacked manner, wherein an interlayer dielectric layer is filled between the first metal layer to be tested and the second metal layer to be tested, the first metal layer to be tested comprises a first metal line to be tested with an equal line width, and the second metal layer to be tested comprises a second metal line to be tested with an equal line width;
a conductive test structure, comprising a first conductive test portion and/or a second conductive test portion, wherein the first conductive test portion and the first metal layer to be tested are distributed on a same layer, the second conductive test portion and the second metal layer to be tested are distributed on a same layer, the first conductive test portion has an equal line width everywhere, the second conductive test portion also has an equal line width everywhere, a distance between the first conductive test portion and the first metal line to be tested is equal everywhere, and a distance between the second conductive test portion and the second metal line to be tested is equal everywhere,
the first metal line to be tested and the second metal line to be tested are connected through a plurality of via holes, and each of the plurality of via holes penetrates through the interlayer dielectric layer;
a first test pad, connected to the first conductive test portion or the second conductive test portion; and
a second test pad, connected to the first metal line to be tested or the second metal line to be tested.

2. The semiconductor test structure according to claim 1, wherein the first metal line to be tested has a serpentine structure, the serpentine structure corresponding to the first metal line to be tested is taken as a first serpentine structure, one side of the first serpentine structure is provided with a plurality of first grooves spaced apart, another side of the first serpentine structure is provided with a plurality of second grooves spaced apart, and the plurality of first grooves and the plurality of second grooves are distributed alternately;
the second metal line to be tested also has a serpentine structure, the serpentine structure corresponding to the second metal line to be tested is taken as a second serpentine structure, one side of the second serpentine structure is provided with a plurality of third grooves spaced apart, another side of the second serpentine structure is provided with a plurality of fourth grooves spaced apart, and the plurality of third grooves and the plurality of fourth grooves are distributed alternately;
the first conductive test portion comprises a first comb-shaped structure and a second comb-shaped structure, wherein the first comb-shaped structure is arranged on one side of the first serpentine structure, and each of comb teeth of the first comb-shaped structure is correspondingly inserted into a different first groove; and the second comb-shaped structure is arranged on another side of the first serpentine structure, and each of comb teeth of the second comb-shaped structure is correspondingly inserted into a different second groove; and
the second conductive test portion comprises a third comb-shaped structure and a fourth comb-shaped structure, wherein the third comb-shaped structure is arranged on one side of the second serpentine structure, and each of comb teeth of the third comb-shaped structure is correspondingly inserted into a different third groove; and the fourth comb-shaped structure is arranged on another side of the second serpentine structure, and each of comb teeth of the fourth comb-shaped structure is correspondingly inserted into a different fourth groove.

3. The semiconductor test structure according to claim 2, wherein the conductive test structure comprises the first conductive test portion, and the first test pad is connected to the first conductive test portion; or the conductive test structure comprises the second conductive test portion, and the first test pad is connected to the second conductive test portion; and
the first serpentine structure and the second serpentine structure are connected through a plurality of via holes, and the second test pad is connected to the first serpentine structure or the second serpentine structure.

4. The semiconductor test structure according to claim 3, wherein the conductive test structure comprises the first conductive test portion, and the first test pad is connected to the first comb-shaped structure or the second comb-shaped structure.

5. The semiconductor test structure according to claim 3, wherein the conductive test structure comprises the second conductive test portion, and the first test pad is connected to the third comb-shaped structure or the fourth comb-shaped structure.

6. The semiconductor test structure according to claim 2, wherein the first test pad is connected to one of the first comb-shaped structure, the second comb-shaped structure, the third comb-shaped structure, or the fourth comb-shaped structure, and the second test pad is connected to the first serpentine structure or the second serpentine structure.

7. The semiconductor test structure according to claim 1, wherein the first metal line to be tested comprises a plurality of first comb-type structures communicating with each other, each of the plurality of first comb-type structures comprises a first comb spine and a plurality of first comb teeth located on one side or two sides of the first comb spine, and a plurality of first tooth gaps spaced apart are surrounded by the plurality of first comb teeth and the first comb spine;
the second metal line to be tested comprises a plurality of second comb-type structures communicating with each other, each of the plurality of second comb-type structures comprises a second comb spine and a plurality of second comb teeth located on one side or two sides of the second comb spine, and a plurality of second tooth gaps spaced apart are surrounded by the plurality of second comb teeth and the second comb spine;
the first conductive test portion comprises third comb-type structures, and each of third comb teeth of each of the third comb-type structures is correspondingly inserted into a different first tooth gap; and
the second conductive test portion comprises fourth comb-type structures, and each of fourth comb teeth of each of the fourth comb-type structures is correspondingly inserted into a different second tooth gap.

8. The semiconductor test structure according to claim 7, wherein the conductive test structure comprises the first conductive test portion, and the first test pad is connected to the first conductive test portion; or the conductive test structure comprises the second conductive test portion, and the first test pad is connected to the second conductive test portion; and
wherein each of the plurality of first comb-type structures and a corresponding second comb-type structure are connected through a plurality of via holes, and the second test pad is electrically connected to the plurality of first comb-type structures or the plurality of second comb-type structures.

9. The semiconductor test structure according to claim 8, wherein the conductive test structure comprises the first conductive test portion, and the first test pad is electrically connected to the third comb-type structures.

10. The semiconductor test structure according to claim 8, wherein the conductive test structure comprises the second conductive test portion, and the first test pad is electrically connected to the fourth comb-type structures.

11. The semiconductor test structure according to claim 7, wherein the conductive test structure comprises the first conductive test portion and the second conductive test portion, and each of the plurality of first comb-type structures and a corresponding second comb-type structure are connected through a plurality of via holes.

12. The semiconductor test structure according to claim 11, wherein the first test pad is electrically connected to the third comb-type structures or the fourth comb-type structures, and the second test pad is electrically connected to the plurality of first comb-type structures or the plurality of second comb-type structures.

13. The semiconductor test structure according to claim 1, wherein the first conductive test portion has a serpentine structure, the serpentine structure corresponding to the first conductive test portion is taken as a third serpentine structure, one side of the third serpentine structure is provided with a plurality of first concave portions spaced apart, another side of the third serpentine structure is provided with a plurality of second concave portions spaced apart, and the plurality of first concave portions and the plurality of second concave portions are distributed alternately;
the second conductive test portion also has a serpentine structure, the serpentine structure corresponding to the second conductive test portion is taken as a fourth serpentine structure, one side of the fourth serpentine structure is provided with a plurality of third concave portions spaced apart, another side of the fourth serpentine structure is provided with a plurality of fourth concave portions spaced apart, and the plurality of third concave portions and the plurality of fourth concave portions are distributed alternately;
the first metal line to be tested comprises a fifth comb-shaped structure and a sixth comb-shaped structure, wherein the fifth comb-shaped structure is arranged on one side of the third serpentine structure, and each of comb teeth of the fifth comb-shaped structure is correspondingly inserted into a different first concave portion; and the sixth comb-shaped structure is arranged on another side of the third serpentine structure, and each of comb teeth of the sixth comb-shaped structure is correspondingly inserted into a different second concave portion; and
the second metal line to be tested comprises a seventh comb-shaped structure and an eighth comb-shaped structure, wherein the seventh comb-shaped structure is arranged on one side of the fourth serpentine structure, and each of comb teeth of the seventh comb-shaped structure is correspondingly inserted into a different third concave portion; and the eighth comb-shaped structure is arranged on another side of the fourth serpentine structure, and each of comb teeth of the eighth comb-shaped structure is correspondingly inserted into a different fourth concave portion.

14. The semiconductor test structure according to claim 13, wherein the conductive test structure comprises the first conductive test portion, and the first test pad is connected to the first conductive test portion; or the conductive test structure comprises the second conductive test portion, and the first test pad is connected to the second conductive test portion; or the conductive test structure comprises the first conductive test portion and the second conductive test portion, and the first test pad is connected to the first conductive test portion or the second conductive test portion; and
the fifth comb-shaped structure and the seventh comb-shaped structure are connected through a plurality of via holes, the sixth comb-shaped structure and the eighth comb-shaped structure are connected through a plurality of via holes, and the second test pad is connected to one of the fifth comb-shaped structure, the sixth comb-shaped structure, the seventh comb-shaped structure, or the eighth comb-shaped structure.

15. A test method for an interlayer overlay shift of metal layers, using a semiconductor test structure for testing,
wherein the semiconductor test structure comprises:
a first metal layer to be tested and a second metal layer to be tested that are distributed in a stacked manner, wherein an interlayer dielectric layer is filled between the first metal layer to be tested and the second metal layer to be tested, the first metal layer to be tested comprises a first metal line to be tested with an equal line width, and the second metal layer to be tested comprises a second metal line to be tested with an equal line width;
a conductive test structure, comprising a first conductive test portion and/or a second conductive test portion, wherein the first conductive test portion and the first metal layer to be tested are distributed on a same layer, the second conductive test portion and the second metal layer to be tested are distributed on a same layer, the first conductive test portion has an equal line width everywhere, the second conductive test portion also has an equal line width everywhere, a distance between the first conductive test portion and the first metal line to be tested is equal everywhere, and a distance between the second conductive test portion and the second metal line to be tested is equal everywhere,
the first metal line to be tested and the second metal line to be tested are connected through a plurality of via holes, and each of the plurality of via holes penetrates through the interlayer dielectric layer;
a first test pad, connected to the first conductive test portion or the second conductive test portion; and
a second test pad, connected to the first metal line to be tested or the second metal line to be tested; and
wherein the test method comprises:
detecting a breakdown voltage between the first metal line to be tested and the first conductive test portion; or detecting a breakdown voltage between the second metal line to be tested and the second conductive test portion;
comparing the breakdown voltage with a preset voltage value, and inferring that a shift phenomenon exists between the first metal line to be tested and the second metal line to be tested in a case that the breakdown voltage exceeds a preset deviation range of the preset voltage value;
sectioning the semiconductor test structure in different directions to obtain microscopic morphology images of sections of the semiconductor test structure in different directions; and
according to the microscopic morphology images, determining an existence of the shift phenomenon, and determining a shift direction.

16. The test method for the interlayer overlay shift of the metal layers according to claim 15, wherein a detection process for detecting the breakdown voltage between the first metal line to be tested and the first conductive test portion comprises: respectively applying a first voltage and a second voltage to the first test pad and the second test pad, wherein in a case that the first metal line to be tested and the first conductive test portion are broken down, a voltage difference between the first voltage and the second voltage is the breakdown voltage.

17. The test method for the interlayer overlay shift of the metal layers according to claim 15, wherein a detection process for detecting the breakdown voltage between the second metal line to be tested and the second conductive test portion comprises: respectively applying a first voltage and a second voltage to the first test pad and the second test pad, wherein in a case that the second metal line to be tested and the second conductive test portion are broken down, a voltage difference between the first voltage and the second voltage is the breakdown voltage.

18. A test method for an interlayer overlay shift of metal layers, using a semiconductor test structure,
wherein the semiconductor test structure comprises:
a first metal layer to be tested and a second metal layer to be tested that are distributed in a stacked manner, wherein an interlayer dielectric layer is filled between the first metal layer to be tested and the second metal layer to be tested, the first metal layer to be tested comprises a first metal line to be tested with an equal line width, and the second metal layer to be tested comprises a second metal line to be tested with an equal line width;
a conductive test structure, comprising a first conductive test portion and/or a second conductive test portion, wherein the first conductive test portion and the first metal layer to be tested are distributed on a same layer, the second conductive test portion and the second metal layer to be tested are distributed on a same layer, the first conductive test portion has an equal line width everywhere, the second conductive test portion also has an equal line width everywhere, a distance between the first conductive test portion and the first metal line to be tested is equal everywhere, and a distance between the second conductive test portion and the second metal line to be tested is equal everywhere,
the first metal line to be tested and the second metal line to be tested are connected through a plurality of via holes, and each of the plurality of via holes penetrates through the interlayer dielectric layer;
a first test pad, connected to the first conductive test portion or the second conductive test portion; and
a second test pad, connected to the first metal line to be tested or the second metal line to be tested; and
wherein the test method comprises:
measuring a resistance between the first metal line to be tested and the first conductive test portion; or measuring a resistance between the second metal line to be tested and the second conductive test portion;
comparing the resistance with a preset resistance value, and inferring that a shift phenomenon exists between the first metal line to be tested and the second metal line to be tested in a case that the resistance exceeds a preset deviation range of the preset resistance value;
sectioning the semiconductor test structure in different directions to obtain microscopic morphology images of sections of the semiconductor test structure in different directions; and
according to the microscopic morphology images, determining an existence of the shift phenomenon, and determining a shift direction.

19. The test method for the interlayer overlay shift of the metal layers according to claim 18, wherein a measurement process for measuring the resistance between the first metal line to be tested and the first conductive test portion comprises: respectively applying a preset current to flow between the first test pad and the second test pad, and measuring a voltage difference between the first metal line to be tested and the first conductive test portion, wherein the resistance is equal to a ratio of the voltage difference to the preset current.

20. The test method for the interlayer overlay shift of the metal layers according to claim 18, wherein a measurement process for measuring the resistance between the second metal line to be tested and the second conductive test portion comprises: respectively applying a preset current to flow between the first test pad and the second test pad, and measuring a voltage difference between the second metal line to be tested and the second conductive test portion, wherein the resistance is equal to a ratio of the voltage difference to the preset current.
